(19) United States
(12) Patent Application Publication
(10) Pub. No.: US 2022/0115457 A1
(43) Pub. Date: Apr. 14, 2022

(54) PIXEL ARRANGEMENT STRUCTURE AND OLED DISPLAY DEVICE

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventors: Jianxin LIU, Shenzhen (CN); Baixiang HAN, Shenzhen (CN)

(21) Appl. No.: 16/764,603

(22) PCT Filed: Apr. 7, 2020
(86) PCT No.: PCT/CN2020/083599

§ 371 Date: May 15, 2020

(30) Foreign Application Priority Data
Mar. 9, 2020 (CN) 202010157033.2

(51) Int. Cl. H01L 27/32

(52) U.S. Cl. CPC H01L 27/3218

(57) ABSTRACT

A pixel arrangement structure is provided in the present application. The pixel arrangement structure, including: a plurality of matrix units with three rows and six columns arranged in array, wherein the matrix unit with three rows and six columns includes two third-order matrix subunits, and each one of the third-order matrix subunits includes 3×3 sub-pixel units. The sub-pixel units with the same color are arranged in a predetermined slash direction in the pixel arrangement structure. An organic light emitting diode (OLED) display device using the pixel arrangement structure is also provided in the present application.

### FIELD OF INVENTION

The present application relates to the field of display technologies, and more particularly, to a pixel arrangement structure and an organic light emitting diode (OLED) display device.

### BACKGROUND OF INVENTION

Organic light emitting diode (OLED) display device has advantages, such as self-lumination, low driving voltages, high luminous efficiency, short response times, high definition and contrast, nearly 180° viewing angles, wide operating temperature, realization of flexible display, large-area full-color display, and so on. OLED display devices are recognized by the industry as the most promising display devices.

With the development of display technology, the requirement for resolution and brightness of display devices is getting higher. However, the fabrication of a high-resolution OLED display requires a fine metal mask (FMM) with high precision, because in the pixels formed by ordinary stripe sub-pixels (RGB stripes), three sub-pixels are arranged within a pixel pitch in a direction perpendicular to the direction of the sub-pixel stripe. When the pixel density is higher than 300 pixels per inch (PPI), the realization of the FMM process is very difficult in the current stage. In addition, due to the improvement of resolution, the distances between the light emitting areas of the sub-pixels are getting smaller, and then the mixing color of the evaporated screen is getting serious. In particular, in the traditional stripe arrangement of three red (R), green (G), and blue (B) sub-pixels, the length of the FMM opening area corresponding to each sub-pixel is longer, resulting in the problems that the linearity control is difficult, the color mixing is prone to occur, and the resolution cannot be improved and the production is difficult if the traditional RGB strip pixel structure is directly applied to an OLED panel.

In summary, in the existing pixel arrangement structure and OLED display device, the use of stripe sub-pixels (RGB stripe) is difficult to realize the preparation of high-resolution products, and the technical problems of preparation are much harder.

### Technical Problems

In the existing pixel arrangement structure and OLED display panel, the use of stripe sub-pixels (RGB stripe) is difficult to realize the preparation of high-resolution products, and there is the technical problem of difficult manufacture.

### SUMMARY OF INVENTION

### Technical Solutions

The embodiments of the present application provide a pixel arrangement structure and an organic light emitting diode (OLED) display device, which can realize the preparation of high-resolution products. In addition, the problems, such as the difficulty of preparation and the harder technical issues caused by the use of stripe sub-pixels (RGB stripe) in the existing pixel arrangement structure and OLED display panel can be solved by the present application.

In a first aspect, the embodiment of the present application provides a pixel arrangement structure, including: a plurality of matrix units with three rows and six columns arranged in an array, wherein the matrix unit with three rows and six columns includes two third-order matrix subunits, and each one of the third-order matrix subunits includes 3×3 sub-pixel units, each row and each column of the third-order matrix subunits are both provided with a first sub-pixel unit, a second sub-pixel unit, and a third sub-pixel unit:

wherein the sub-pixel units with the same color are arranged in a predetermined slash direction D in the pixel arrangement structure, the predetermined slash direction includes a first sub-slash direction D1 or a second sub-slash direction D2, the first sub-slash direction D1 is parallel to a first diagonal of the third-order matrix subunit, and the second sub-slash direction D2 is parallel to a second diagonal of the third-order matrix subunit.

In the pixel arrangement structure provided by the embodiment of the present application, each one of the third-order matrix subunits has three first sub-pixel units, three second sub-pixel units, and three third sub-pixel units.

In the pixel, arrangement structure provided by the embodiment of the present application, in each one of the third-order matrix subunits, the corresponding colors of the sub-pixel units in each row are arranged in different orders, and the corresponding colors of the sub-pixel units in each column are arranged in different orders.

In the pixel arrangement structure provided by the embodiment of the present application, the pixel arrangement structure is prepared by a line bank technology.

In the pixel arrangement structure provided by the embodiment of the present application, an angle between a moving direction of a printer head and a shorter edge of a carrier substrate is 45 degree.

In the pixel arrangement structure provided by the embodiment of the present application, a shape of each one of the sub-pixel units is a rectangle, and a length to width ratio of the rectangle is 2:1.

In the pixel arrangement structure provided by the embodiment of the present application, an area ratio of the first sub-pixel unit, the second sub-pixel unit, and the third sub-pixel unit is 1:1:1.

In the pixel arrangement structure provided by the embodiment of the present application, the first sub-pixel unit corresponds to a red sub-pixel unit (R), the second sub-pixel unit corresponds to a green sub-pixel unit (G), and the third sub-pixel unit corresponds to a blue sub-pixel unit (B).

In a second aspect, the embodiment of the present application further provides a pixel arrangement structure, including: a plurality of matrix units with three rows and six columns arranged in an array, wherein the matrix unit with three rows and six columns includes two third-order matrix subunits, and each one of the third-order matrix subunits includes 3×3 sub-pixel units, each row and each column of the third-order matrix subunits are both provided with a first sub-pixel unit, a second sub-pixel unit, and a third sub-pixel unit:

wherein the sub-pixel units with the same, color are arranged in a predetermined slash direction D in the pixel arrangement structure.

In the pixel arrangement structure provided by the embodiment of the present application, each one of the third-order matrix subunits has three first sub-pixel units, three second sub-pixel units, and three third sub-pixel units.

In the pixel arrangement structure provided by the embodiment of the present application, in each one of the third-order matrix subunits, the corresponding colors of the sub-pixel units in each row are arranged in different orders, and the corresponding colors of the sub-pixel units in each column are arranged in different orders.

In the pixel arrangement structure provided by the embodiment of the present application, the pixel arrangement structure is prepared by a line bank technology.

In the pixel arrangement structure provided by the embodiment of the present application, an angle between a moving direction of a printer head and a shorter edge of a carrier substrate is 45 degree.

In the pixel arrangement structure provided by the embodiment of the present application, a shape of each one of the sub-pixel units is a rectangle, and a length to width ratio of the rectangle is 2:1.

In the pixel arrangement structure provided by the embodiment of the present application, an area ratio of the first sub-pixel unit, the second sub-pixel unit, and the third sub-pixel unit is 1:1:1.

In the pixel arrangement structure provided by the embodiment of the present application, the first sub-pixel unit corresponds to a red sub-pixel unit (R), the second sub-pixel unit corresponds to a green sub-pixel unit (G), and the third sub-pixel unit corresponds to a blue sub-pixel unit (B).

In a third aspect, the embodiment of the present application further provides an organic light emitting diode (OLED) display device, including the pixel arrangement structure.

Beneficial Effect:

Compared with the existing technology, the embodiments of the present application provide a pixel arrangement structure and an organic light emitting diode (OLED) display device, in which the sub-pixels with the same color are arranged in a line in a slash direction. While realizing high-resolution products, the arrangement is compatible with the line bank technology for mass production of OLED printing.

### DESCRIPTION OF DRAWINGS

FIG. 1 is a schematic diagram of a pixel arrangement structure provided by a first embodiment of the present application.

FIG. 2 is a schematic diagram of a pixel arrangement structure provided by a second embodiment of the present application.

FIG. 3 is a schematic diagram of a moving direction of a printer head, which prepares the pixel arrangement structure provided by the embodiments of the present application.

### DETAILED DESCRIPTION OF PREFERRED EMBODIMENTS

In the technology achieving high resolution and high PPI, the traditional RGB strip arrangement encounters some problems, such as insufficient wiring space, low yields, and small aperture ratios. In particular, for OLED display devices, the printing equipment has difficulty in printing high PPI products due to the limitations of precision and technology. Manufacturers in this industry propose their own pixel sub pixel rendering (SPR) technical solutions, which are widely used in mobile phone screens and television screens. SPR is a pixel rendering technology. Each pixel is composed of two sub-pixels, which are periodically arranged in the order of “red+green” or “green+blue” or “blue+red”. This arrangement can improve the PPI of the product, reduce the channel number of the driving IC, increase the aperture ratio, and reduce the power consumption of the product.

However, the existing SPR technical solution is not suitable for a printing technology for mass production of OLED in the future, i.e. a line bank technology, because the RGB sub-pixels are arranged in a line in the horizontal direction, the vertical direction, and the diagonal direction. The embodiments of the present application focus on the problems that in the existing pixel arrangement structure and OLED display device, the used of a pixel arrangement structure composed of stripe sub-pixels (RGB stripe) has difficulty in achieving the preparation of high-resolution products and has the difficult manufacture. The embodiments of present application can solve the problems.

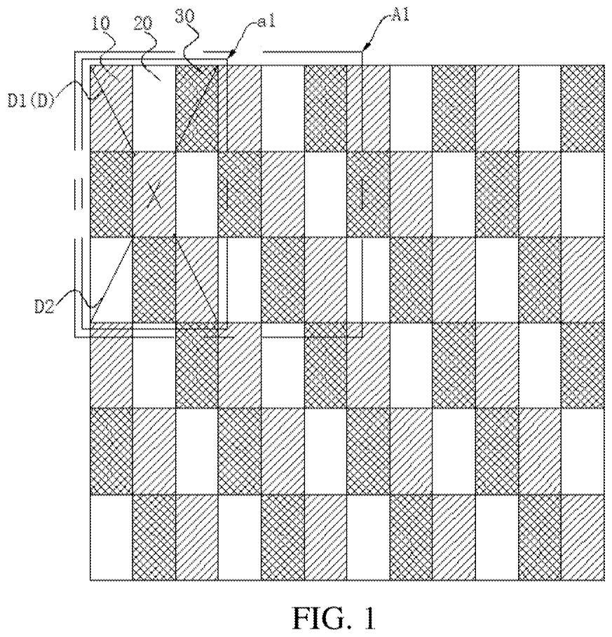

As shown in FIG. 1, FIG. 1 is a schematic diagram of a pixel arrangement structure provided by a first embodiment of the present application. The pixel arrangement structure includes a plurality of matrix units with three rows and six columns A1 arranged in an array, wherein the matrix unit with three rows and six columns A1 includes two third-order matrix subunits, and each one of the third-order matrix subunits a1 includes 3×3 sub-pixel units, each row and each column of the third-order matrix subunits a1 are both provided with first sub-pixel units 10, second sub-pixel units 20, and third sub-pixel units 30.

Specifically, the sub-pixel units with the same color are arranged in a predetermined slash direction B in the pixel arrangement structure.

It should be noted that, first, the matrix unit with three rows and six columns A1 refers to the smallest repeating unit in the pixel arrangement structure; that is, there may be other repeating units in the pixel arrangement structure, but the other repeating units must be based on the matrix unit with three rows and six columns A1.

Second, each row and each column of the third-order matrix subunits a1 are both provided with the first sub-pixel unit 10, the second sub-pixel unit 20, and the third sub-pixel unit 30. That is, the first sub-pixel units 10, the second sub-pixel units 20, and the three sub-pixel units 30 are arranged in the third-order matrix subunit a1 in a 3×3 manner, and each one of the sub-pixel units mentioned above is arranged in each row and each column.

On this basis, the matrix unit with three rows and six columns A1 includes two third-order matrix subunits a1. In the first embodiment of the present application, the arrangement of each one of the third-order matrix subunit a1 just need to satisfy the above requirements, and the arrangement of each one of the third-order matrix subunit a1 may not be completely the same.

Third, any one of the first sub-pixel unit 10, the second sub-pixel unit 20, and the third sub-pixel unit 30 may correspond to any one of a red sub-pixel unit (R), a green sub-pixel unit (G), and a blue sub-pixel unit (B). Preferably, the first sub-pixel unit 10 corresponds to the red sub-pixel unit (R), the second sub-pixel unit 20 corresponds to the green sub-pixel unit (G), and the third sub-pixel unit 30 corresponds to the blue sub-pixel unit (B).

In the first embodiment of the present application, the predetermined slash direction D is a first sub-slash direction D1, and the first sub-slash direction D1 is parallel to a first diagonal of the third-order matrix subunit a1.

Specifically, each one of the third-order matrix subunits a1 has three first sub-pixel units 10, three second sub-pixel units 20, and three third sub-pixel units 30.

Specifically, in each one of the third-order matrix subunits at the corresponding colors of the sub-pixel units in each row are arranged in different orders, and the corresponding colors of the sub-pixel units in each column are arranged in different orders.

Specifically, a shape of each one of the sub-pixel units is a rectangle, and a length to width ratio of the rectangle is 2:1.

Specifically, an area ratio of the first sub-pixel unit the second sub-pixel unit 20, and the third sub-pixel unit 30 is 1:1:1.

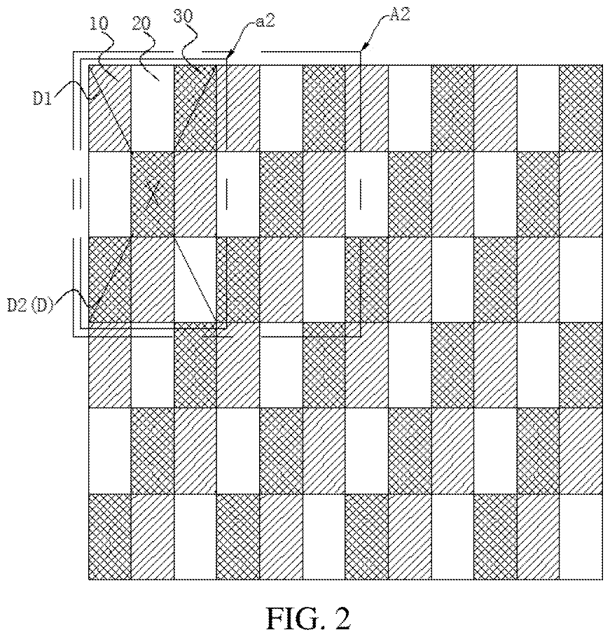

As shown in FIG. 2, FIG. 2 is a schematic diagram of a pixel arrangement structure provided by a second embodiment of the present application. The pixel arrangement structure includes a plurality of matrix units with three rows and six columns A2 arranged in an array, wherein the matrix unit with three rows and six columns A2 includes two third-order matrix subunits, and each one of the third-order matrix subunits a2 includes 3×3 sub-pixel units, each row and each column of the third-order matrix subunits a2 are both provided with first sub-pixel units 10, second sub-pixel units 20, and third sub-pixel units 30.

Specifically, the sub-pixel units with the same color are arranged in a predetermined slash direction D in the pixel arrangement structure.

It should be noted that, first, the matrix unit with three rows and six columns A2 refers to the smallest repeating unit in the pixel arrangement structure; that is, there may be other repeating units in the pixel arrangement structure, but the other repeating units must be based on the matrix unit with three rows and six columns A2.

Second, each row and each column of the third-order matrix subunits a2 are both provided with the first sub-pixel unit 10, the second sub-pixel unit 20, and the third sub-pixel unit 30. That is, the first sub-pixel units 10, the second sub-pixel units 20, and the three sub-pixel units 30 are arranged in the third-order matrix subunit a2 in a 3×3 manner, and each one of the sub-pixel units mentioned above is arranged in each row and each column.

On this basis, the matrix unit with three rows and six columns A2 includes two third-order matrix subunits a2. In the first embodiment of the present application, the arrangement of each one of the third-order matrix subunit a2 just need to satisfy the above requirements, and the arrangement of each one of the third-order matrix subunit a2 may not be completely the same.

Third, any one of the first sub-pixel unit 10, the second sub-pixel unit 20, and the third sub-pixel unit 30 may correspond to any one of a red sub-pixel unit (R), a green sub-pixel unit (G), and a blue sub-pixel unit (B). Preferably, the first sub-pixel unit 10 corresponds to the red sub-pixel unit (R), the second sub-pixel unit 20 corresponds to the green sub-pixel unit (G), and the third sub-pixel unit 30 corresponds to the blue sub-pixel unit (B).

In the second embodiment of the present application, the predetermined slash direction D is a second sub-slash direction D2, and the second sub-slash direction D2 is parallel to a second diagonal of the third-order matrix subunit a2.

Specifically, each one of the third-order matrix subunits a2 has three first sub-pixel units 10, three second sub-pixel units 20, and three third sub-pixel units 30.

Specifically, in each one of the third-order matrix subunits a2, the corresponding colors of the sub-pixel units in each row are arranged in different orders, and the corresponding colors of the sub-pixel units in each column are arranged in different orders.

Specifically, a shape of each one of the sub-pixel units is a rectangle, and a length to width ratio of the rectangle is 2:1.

Specifically, an area ratio of the first sub-pixel unit the second sub-pixel unit 20, and the third sub-pixel unit 30 is 1:1:1.

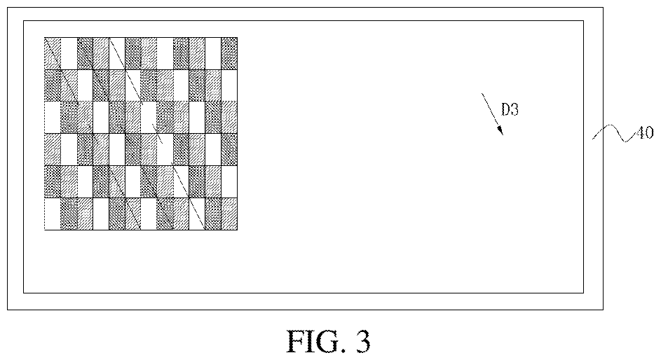

As shown in FIG. 3, FIG. 3 is a schematic diagram of a moving direction of a printer head, which prepares the pixel arrangement structure provided by the embodiments of the present application. The pixel arrangement structure is prepared by a line bank technology. The line bank technology can realize the mass production of the OLED display device.

Specifically, compared with the pixel arrangement structure formed by the ordinary stripe sub-pixels (RGB stripe) applied in the line bank technology, a moving direction D3 of a printer head is changed to angle with a shorter edge of a substrate at 45 degrees, wherein in the pixel arrangement structure formed by the traditional stripe sub-pixels (RGB stripe), the moving direction D3 of the printer head is parallel to an edge of a substrate. That is, an angle between the moving direction D3 of the printer head and the shorter edge of a carrier substrate 40 is 45 degrees.

The pixel arrangement structure provided by the embodiments of the present application belongs to a new SPR arrangement design of OLED pixel. While realizing the preparation of the high-resolution products, the arrangement is compatible with is a printing technology for mass production of OLED in the future, i.e. the line bank technology.

The embodiment of the present application further provides an OLED display device, and the OLED display device includes the pixel arrangement structure described above.

The embodiments of the present application provide a pixel arrangement structure and an organic light emitting diode (OLED) display device, in which the sub-pixels with the same color are arranged in a line in a slash direction. While realizing high-resolution products, the arrangement is compatible with the line bank technology for mass production of OLED printing.

For the specific implementation of the above operations, refer to the previous embodiments, and the details are not repeated herein.

In summary, the pixel arrangement structure and the OLED display device provided by the embodiments of the present application can avoid the cracks generated during the bending process of the flexible display panel due to the poor ductility of the inorganic layer during the cutting process, on the premise of not increase the mask and process flow. That further ensures the display performance of the flexible display panel.

In view of the above, although the present invention has been disclosed by way of preferred embodiments, the above preferred embodiments are not intended to limit the present invention, and one of ordinary skill in the art, without departing from the spirit and scope of the invention, the scope of protection of the present invention is defined by the scope of the claims.

What is claimed is:

1. A pixel arrangement structure, comprising:
a plurality of matrix units with three rows and six columns arranged in an array, wherein the matrix unit with three rows and six columns comprises two third-order matrix subunits, and each one of the third-order matrix subunits comprises 3×3 sub-pixel units, each row and each column of the third-order matrix subunits are both provided with a first sub-pixel unit, a second sub-pixel unit, and a third sub-pixel unit;
wherein the sub-pixel units with the same color are arranged in a predetermined slash direction D in the pixel arrangement structure, the predetermined slash direction comprises a first sub-slash direction D1 or a second sub-slash direction D2, the first sub-slash direction D1 is parallel to a first diagonal of the third-order matrix subunit, and the second sub-slash direction D2 is parallel to a second diagonal of the third-order matrix subunit.

2. The pixel arrangement structure according to claim 1, wherein each one of the third-order matrix subunits has three first sub-pixel units, three second sub-pixel units, and three third sub-pixel units.

3. The pixel arrangement structure according to claim 1, wherein in each one of the third-order matrix subunits, the corresponding colors of the sub-pixel units in each row are arranged in different orders, and the corresponding colors of the sub-pixel units in each column are arranged in different orders.

4. The pixel arrangement structure according to claim 1, wherein the pixel arrangement structure is prepared by a line bank technology.

5. The pixel arrangement structure according to claim 4, wherein an angle between a moving direction of a printer head and a shorter edge of a carrier substrate is 45 degrees.

6. The pixel arrangement structure according to claim 1, wherein a shape of each one of the sub-pixel units is a rectangle, and a length to width ratio of the rectangle is 2:1.

7. The pixel arrangement structure according to claim 1, wherein an area ratio of the first sub-pixel unit, the second sub-pixel unit, and the third sub-pixel unit is 1:1:1.

8. The pixel arrangement structure according to claim 1, wherein the first sub-pixel unit corresponds to a red sub-pixel unit (R), the second sub-pixel unit corresponds to a green sub-pixel unit (G), and the third sub-pixel unit corresponds to a blue sub-pixel unit (B).

9. A pixel arrangement structure, comprising:
a plurality of matrix units with three rows and six columns arranged in an array, wherein the matrix unit with three rows and six columns comprises two third-order matrix subunits, and each one of the third-order matrix subunits comprises 3×3 sub-pixel units, each row and each column of the third-order matrix subunits are both provided with a first sub-pixel unit, a second sub-pixel unit, and a third sub-pixel unit;
wherein the sub-pixel units with the same color are arranged in a predetermined slash direction D in the pixel arrangement structure.

10. The pixel arrangement structure according to claim 9, wherein each one of the third-order matrix subunits has three first sub-pixel units, three second sub-pixel units, and three third sub-pixel units.

11. The pixel arrangement structure according to claim 9, wherein in each one of the third-order matrix subunits, the corresponding colors of the sub-pixel units in each row are arranged in different orders, and the corresponding colors of the sub-pixel units in each column are arranged in different orders.

12. The pixel arrangement structure according to claim 9, wherein the pixel arrangement structure is prepared by a line bank technology.

13. The pixel arrangement structure according to claim 12, wherein an angle between a moving direction of a printer head and a shorter edge of a carrier substrate is 45 degree.

14. The pixel arrangement structure according to claim 9, wherein a shape of each one of the sub-pixel units is a rectangle, and a length to width ratio of the rectangle is 2:1.

15. The pixel arrangement structure according to claim 9, wherein an area ratio of the first sub-pixel unit, the second sub-pixel unit, and the third sub-pixel unit is 1:1:1.

16. The pixel arrangement structure according to claim 9, wherein the first sub-pixel unit corresponds to a red sub-pixel unit (R), the second sub-pixel unit corresponds to a green sub-pixel unit (G), and the third sub-pixel unit corresponds to a blue sub-pixel unit (B).

17. An organic light emitting diode (OLED) display device, comprising: a pixel arrangement structure according to claim 1.

18. An organic light emitting diode (OLED) display device, comprising: a pixel arrangement structure according to claim 9.
